(19) United States
(12) Patent Application Publication
(10) Pub. No.: US 2025/0044706 A1
(43) Pub. Date: Feb. 6, 2025

(54) METHOD OF PREDICTING EUV DOSE, METHOD OF DESIGNING PAG USING THE SAME, AND METHOD OF MANUFACTURING SEMICONDUCTOR DEVICE USING THE SAME

(71) Applicant: Samsung Electronics Co., Ltd., Suwon-sI (KR)

(72) Inventors: Ji Young PARK, Suwon-si (KR); Daekeon KIM, Suwon-si (KR); Seungyeol BAEK, Suwon-si (KR); Giyoung SONG, Suwon-si (KR); Hyun-Ji SONG, Suwon-si (KR); Thanh Cuong NGUYEN, Suwon-si (KR); Suk Koo HONG, Suwon-si (KR)

(73) Assignee: Samsung Electronics Co., Ltd., Suwon-si (KR)

(21) Appl. No.: 18/674,355

(22) Filed: May 24, 2024

(30) Foreign Application Priority Data
Jul. 31, 2023 (KR) 10-2023-0099353
Sep. 20, 2023 (KR) 10-2023-0125348

(51) Int. Cl. G03F 7/00

(52) U.S. Cl. CPC G03F 7/705

(57) ABSTRACT

In a method of predicting extreme ultraviolet (EUV) dose, an entire photochemical reaction mechanism until a photoacid generator (PAG) molecule releases a proton from a PAG-cation under EUV exposure may be analyzed. A lowest unoccupied molecular orbital (LUMO) energy level may be obtained by performing a simulation for structural optimization of the PAG-cation. An additional parameter different from the LUMO energy level may be obtained by performing a simulation for structural optimization of at least one intermediate molecular structure formed by the entire photochemical reaction mechanism. A two-parameter linear regression model for predicting the EUV dose may be obtained based on the LUMO energy level and the additional parameter.

### CROSS-REFERENCE TO RELATED APPLICATION

This application claims priority under 35 USC § 119 to Korean Patent Application No. 10-2023-0099353 filed on Jul. 31, 2023 and to Korean Patent Application No. 10-2023-0125348 filed on Sep. 20, 2023 in the Korean Intellectual Property Office (KIPO), the contents of which are herein incorporated by reference in their entirety.

### BACKGROUND

### 1. Technical Field

Example embodiments relate generally to semiconductor integrated circuits, and more particularly to methods of predicting extreme ultraviolet (EUV) dose, methods of designing photoacid generators (PAGs) using the methods of predicting the EUV dose, and methods of manufacturing semiconductor devices using the methods of designing the PAGs.

### 2. Description of the Related Art

In manufacturing a highly integrated semiconductor device, pattern miniaturization is essential. Recently, as designs of semiconductor devices rapidly decrease in size, various lithography techniques for implementing fine patterns have been developed. For example, an extreme ultraviolet (EUV) lithography technique using an exposure process by EUV with a wavelength of about 13.5 nanometers (nm) is a next-generation technique to replace a lithography process using a KrF excimer laser (248 nm) and an ArF excimer laser (193 nm), and various studies on EUV lithography techniques are being conducted.

An EUV lithography process has a different mechanism of action from a lithography process using a KrF excimer laser and an ArF excimer laser. In an EUV lithography process, the entire process is carried out under vacuum. In an EUV lithography equipment, power required to irradiate a laser from a light source may be insufficient, so there may be a limitation in increasing the dose sufficiently to generate a required amount of acid from a photoacid generator in a photoresist material during exposure. Therefore, there is a demand for a photoacid generator with high acid generation efficiency and dose improvement effect.

### SUMMARY

At least one example embodiment of the present disclosure provides a method of efficiently predicting extreme ultraviolet (EUV) dose by a photoacid generator (PAG).

At least one example embodiment of the present disclosure provides a method of efficiently designing a photoacid generator (PAG) having improved lithography characteristics using the method of predicting the EUV dose.

At least one example embodiment of the present disclosure provides a method of efficiently manufacturing a semiconductor device using the method of designing the PAG.

According to example embodiments, a method of predicting an extreme ultraviolet (EUV) dose may be performed by executing program code by at least one processor, and the program code may be stored in a non-transitory computer readable medium. The method may include analyzing an entire photochemical reaction mechanism until a photoacid generator (PAG) molecule releases a proton from a PAG-cation under EUV exposure; obtaining a lowest unoccupied molecular orbital (LUMO) energy level by performing a simulation for structural optimization of the PAG-cation; obtaining an additional parameter different from the LUMO energy level by performing a simulation for structural optimization of at least one intermediate molecular structure formed by the entire photochemical reaction mechanism; and obtaining a two-parameter linear regression model for predicting the EUV dose based on the LUMO energy level and the additional parameter.

According to example embodiments, a method of designing a photoacid generator (PAG) may be performed by executing program code by at least one processor, and the program code may be stored in a non-transitory computer readable medium. The method may include predicting a first extreme ultraviolet (EUV) dose in an EUV lithography process based on the EUV lithography process using a first PAG molecule; predicting a second EUV dose in the EUV lithography process based on the EUV lithography process using a second PAG molecule, the second PAG molecule being different from the first PAG molecule; and determining a suitability of the second PAG molecule based on the first EUV dose and the second EUV dose. The predicting the first EUV dose may include analyzing a first entire photochemical reaction mechanism until the first PAG molecule releases a first proton from a first PAG-cation under EUV exposure, obtaining a first lowest unoccupied molecular orbital (LUMO) energy level by performing a simulation for structural optimization of the first PAG-cation, obtaining a first additional parameter different from the first LUMO energy level by performing a simulation for structural optimization of at least one first intermediate molecular structure formed by the first entire photochemical reaction mechanism, and obtaining a first two-parameter linear regression model for predicting the first EUV dose based on the first LUMO energy level and the first additional parameter.

According to example embodiments, a method of predicting an extreme ultraviolet (EUV) dose may be performed by executing program code by at least one processor, and the program code may be stored in a non-transitory computer readable medium. The method may include analyzing an entire photochemical reaction mechanism until a photoacid generator (PAG) molecule releases a proton from a PAG-cation under EUV exposure; obtaining a lowest unoccupied molecular orbital (LUMO) energy level by performing a simulation for structural optimization from the PAG-cation to the first molecular structure; obtaining an amount of overall energy change from the third molecular structure to the fifth molecular structure by performing a simulation for structural optimization from the third molecular structure to the fifth molecular structure; and obtaining a two-parameter linear regression model for predicting the EUV dose based on the LUMO energy level and the amount of overall energy change. In the entire photochemical reaction mechanism: a first molecular structure may be formed by electron trapping; a second molecular structure and a second-first molecular structure may be formed by internal excitation; a second-second molecular structure may be formed proceeding from the second molecular structure or the second-first molecular structure; a third molecular structure may be formed proceeding from the first molecular structure; a fourth molecular structure may be formed proceeding from the second molecular structure, the second-first molecular structure, or the third molecular structure; a fifth molecular structure may be formed proceeding from the fourth molecular structure or the second-second molecular structure and may correspond to a molecular structure after the proton is released from the PAG-cation. The obtaining the additional parameter may include obtaining an amount of oxidation energy change by performing a simulation for structural optimization of the third molecular structure; obtaining an amount of deprotonation energy change by performing a simulation for structural optimization of the fourth molecular structure; and calculating the amount of overall energy change based on the amount of oxidation energy change and the amount of deprotonation energy change. The PAG-cation may be a triphenylsulfonium (TPS)-cation or the PAG-cation may have a structure in which at least a portion of each phenyl ring included in the TPS-cation is modified.

According to example embodiments, a method of manufacturing a semiconductor device may include designing a photoacid generator (PAG) used in an extreme ultraviolet (EUV) lithography process by executing program code by at least one processor, the program code being stored in a non-transitory computer readable medium; and fabricating the semiconductor device based on a result of the designing the PAG. The designing the PAG may include predicting a first EUV dose in an EUV lithography process when using a first PAG molecule, predicting a second EUV dose in the EUV lithography process when using a second PAG molecule different from the first PAG molecule, and determining a suitability of the second PAG molecule based on the first EUV dose and the second EUV dose. The predicting the first EUV dose may include analyzing a first entire photochemical reaction mechanism until the first PAG molecule releases a first proton from a first PAG-cation under EUV exposure, obtaining a first lowest unoccupied molecular orbital (LUMO) energy level by performing a simulation for structural optimization of the first PAG-cation, obtaining a first additional parameter different from the first LUMO energy level by performing a simulation for structural optimization of at least one first intermediate molecular structure formed by the first entire photochemical reaction mechanism, and obtaining a first two-parameter linear regression model for predicting the first EUV dose based on the first LUMO energy level and the first additional parameter.

In the method of predicting the EUV dose, the method of designing the PAG, and the method of manufacturing the semiconductor device according to example embodiments, the photochemical reaction and acid generation process of PAG-cation in both “electron trapping” and “internal excitation” mechanisms may be systematically investigated using atomic-scale molecules modeling. For example, the entire photoreaction mechanism of the PAG-cation under the EUV exposure may be investigated, and the key parameter (e.g., the additional parameter affecting the EUV dose in addition to the LUMO energy level) for the acid generation and EUV exposure dose may be found. In addition, a two-parameter-based prediction model for PAG performance on EUV exposure dose may be developed based on experimental data. Finally, the design rules for synthesize new EUV PAG materials with superior properties may be suggested.

When the two-parameter linear regression model for the EUV dose is obtained using the LUMO energy level and the additional parameter according to example embodiments, the EUV dose may be efficiently predicted and the prediction consistency may be improved or enhanced based on the two-parameter linear regression model. In addition, a new PAG molecule that has superior performance (e.g., high acid generation yield) and is for forming patterns even at low EUV dose in the EUV lithography process, as compared with the existing PAG molecule, may be efficiently designed based on the method of predicting the EUV dose according to example embodiments.

### BRIEF DESCRIPTION OF THE DRAWINGS

Illustrative, non-limiting example embodiments will be more clearly understood from the following detailed description taken in conjunction with the accompanying drawings.

FIG. 1 is a flowchart illustrating a method of predicting extreme ultraviolet (EUV) dose according to example embodiments.

FIGS. 2 and 3 are block diagrams illustrating a prediction and design system according to example embodiments.

FIGS. 4 and 5 are diagrams for describing a method of predicting EUV dose according to example embodiments.

FIGS. 6, 7, 8 and 9 are flowcharts illustrating examples of obtaining an additional parameter in FIG. 1.

FIG. 10 is a flowchart illustrating a method of designing a photoacid generator (PAG) according to example embodiments.

FIG. 11 is a flowchart illustrating an example of determining a suitability of a second PAG molecule in FIG. 10.

FIGS. 12A, 12B, 13A and 13B are diagrams for describing a method of designing a PAG according to example embodiments.

FIG. 14 is a flowchart illustrating a method of manufacturing a semiconductor device according to example embodiments.

FIGS. 15A and 15B are diagrams for describing a method of manufacturing a semiconductor device according to example embodiments.

### DETAILED DESCRIPTION OF THE EMBODIMENTS

Various example embodiments will be described more fully with reference to the accompanying drawings, in which embodiments are shown. The present disclosure may, however, be embodied in many different forms and should not be construed as limited to the embodiments set forth herein. Like reference numerals refer to like elements throughout this application.

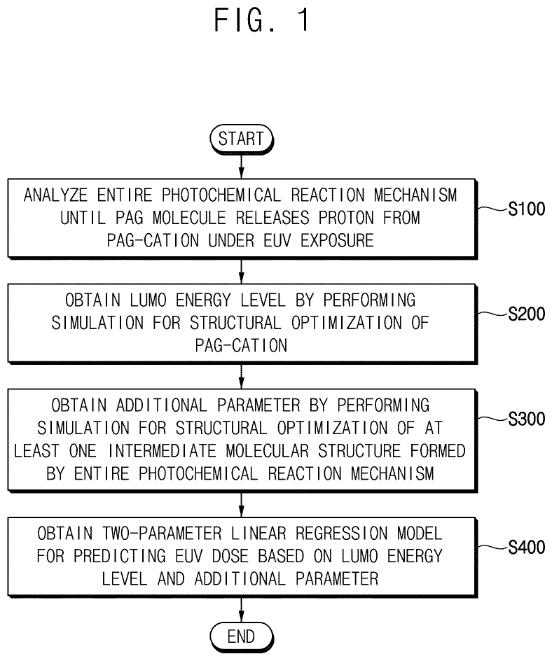

FIG. 1 is a flowchart illustrating a method of predicting extreme ultraviolet (EUV) dose according to example embodiments.

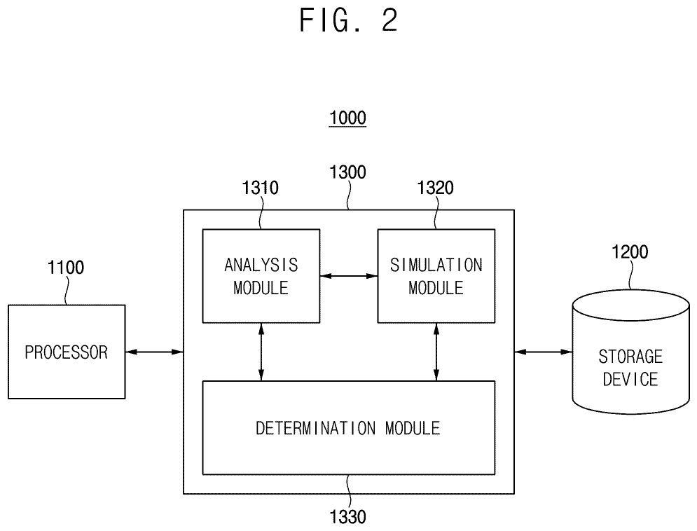

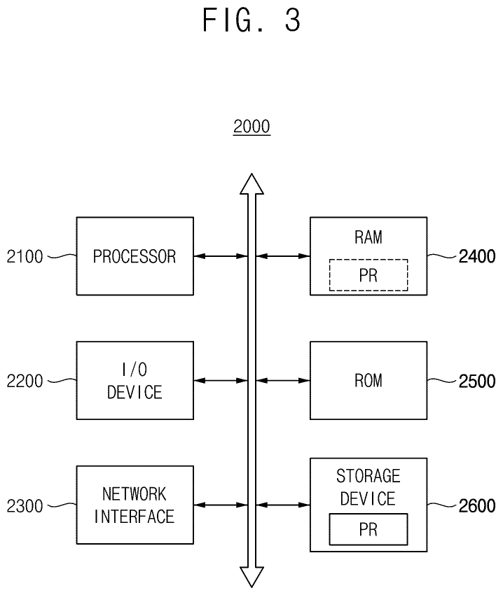

Referring to FIG. 1, a method of predicting extreme ultraviolet (EUV) dose according to example embodiments may be performed in a design process for a photoacid generator (PAG) that is included in a specific material used in a manufacturing process of a semiconductor device (or semiconductor integrated circuit). For example, the material including the PAG may include a photoresist used in an EUV lithography process. For example, the method of predicting the EUV dose according to example embodiments may be performed on a system and/or tool for performing an atomic-scale molecules (or materials) simulation. For example, the system and/or the tool for performing the atomic-scale molecules simulation may include a program (or program code) that includes a plurality of instructions executed by at least one processor. The system and/or the tool will be described with reference to FIGS. 2 and 3.

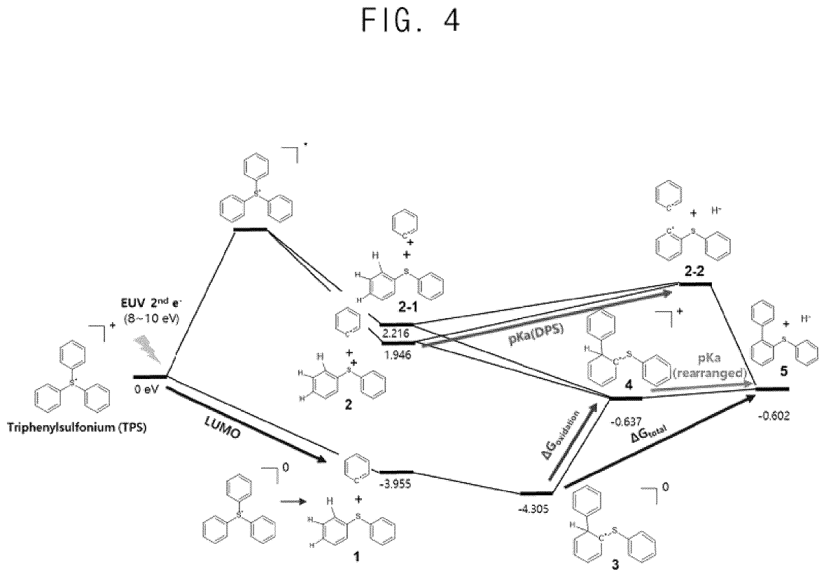

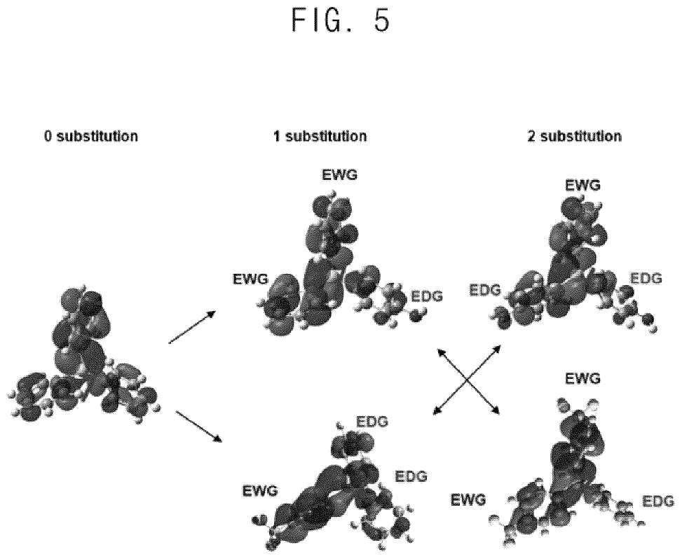

In the method of predicting the EUV dose (or EUV exposure dose) according to example embodiments, the entire (or overall) photochemical reaction mechanism until a PAG molecule releases a proton from a PAG-cation (or PAG-cation molecule) under EUV exposure is analyzed (operation S100). The entire photochemical reaction mechanism will be described with reference to FIGS. 4 and 5.

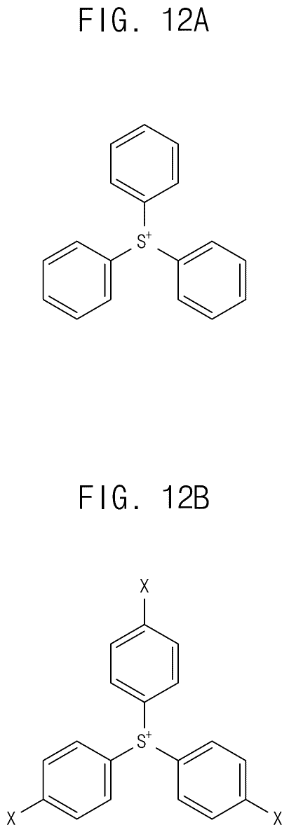

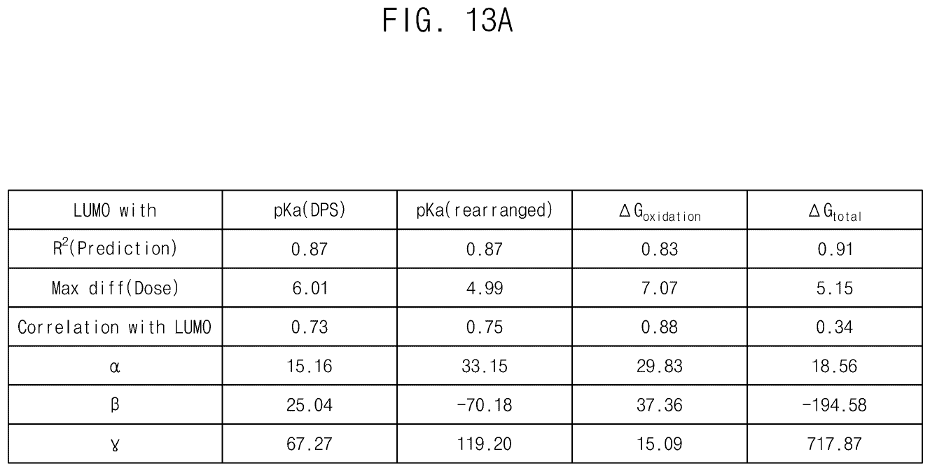

In some example embodiments, the PAG-cation may be or may include a triphenylsulfonium (TPS)-cation (or TPS-cation molecule) that has been widely used. In some example embodiments, the PAG-cation may have a structure in which at least a portion of the TPS-cation is modified, e.g., a structure in which at least a portion of each phenyl ring or benzene ring included in the TPS-cation is modified. Examples of the PAG-cation will be described with reference to FIGS. 12A and 12B.

A lowest unoccupied molecular orbital (LUMO) energy level is obtained by performing a simulation for structural optimization of the PAG-cation (operation S200). The LUMO energy level may be one of key parameters (or factors or variables) known to affect the EUV dose.

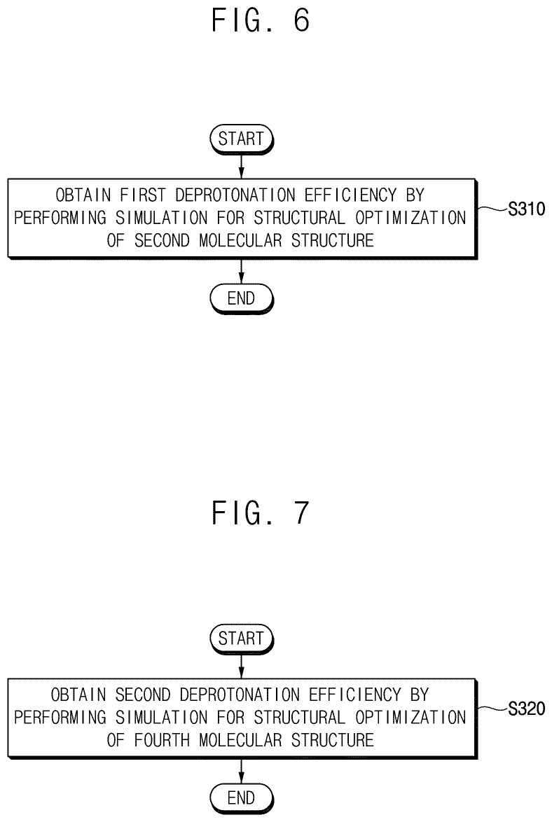

An additional parameter different from the LUMO energy level is obtained by performing a simulation for structural optimization of at least one intermediate molecular structure formed by the entire photochemical reaction mechanism (operation S300). The additional parameter may be a parameter that affects the EUV dose in addition to the LUMO energy level. Examples of the additional parameter associated with or related to the entire photochemical reaction mechanism will be described with reference to FIG. 4, and examples of operation S300 will be described with reference to FIGS. 6 through 9.

A two-parameter linear regression model for predicting the EUV dose is obtained based on the LUMO energy level and the additional parameter (operation S400). For example, the two-parameter linear regression model may be obtained by Equation 1.

$$Dose = α \times L U M O + β \times {P}_{after} + γ \qquad [ Equation l ]$$

In Equation 1, “Dose” denotes the EUV dose, “LUMO” denotes the LUMO energy level, P_{after} denotes the additional parameter, and α, β and γ denote coefficients, respectively. For example, α may correspond to the contribution of the LUMO energy level, and β may correspond to the contribution of the additional parameter.

In a manufacturing process of a semiconductor device, a photolithography process (or simply lithography process) is a patterning process of a thin film by exposing a photo-sensitive material (e.g., photoresist) under a light, then be selectively dissolved to fabricate a desired shape on nanometer length scales. A minimum feature size, that is defined as a minimum size of each element on a chip, such as a distance between a source and a drain of a transistor, may be decreased by decreasing a wavelength of the light used in the lithography process. A conventional lithography process that uses deep ultraviolet (DUV) light with about 248 nm wavelength (from KrF excimer laser) and about 193 nm wavelength (from ArF excimer laser), allow the minimum feature size down to about 50 nm. To further scale down the minimum feature size, EUV lithography technology, which uses the EUV with about 13.5 nm wavelength, has been developed, and recently the minimum feature size may scale down to about 10 nm in a single exposure patterning.

One of major challenges in the EUV lithography process is the “stochastic issue” that the photons are sparsely distributed in the exposed area. Hence, high EUV exposure dose (e.g., low sensitivity) may be required to avoid the deterioration of line-width roughness (LWR), line-edge roughness (LER), resolution, etc. However, EUV exposure systems may cause higher costs than conventional DUV systems because of the high power density and high cost of maintenance. As a result, the EUV exposure systems may cause low throughput and low productivity. Therefore, for mass production (or high volume manufacturing), it is necessary to develop the high performance photoresist materials that can form patterns even at low EUV exposure dose (e.g., high sensitivity).

Similar to KrF/ArF technology, EUV photoresists typically consist of chemical amplified resist (CAR) composite composed of a polymer, a photoacid generator (PAG), and a quencher. However, the photon energy of EUV light (e.g., about 92 eV) may be much higher than that of KrF light (e.g., about 5 eV) and ArF light (e.g., about 6.4 eV). Thus, the photochemical processes of the EUV photoresists may differ from those in the previous KrF/ArF photoresists. Currently, in the widely accepted photochemical processes of the EUV CAR, polymer resin, which is a main part of the resist, may absorb high energy EUV photons and then generate secondary electrons. PAG molecules may adsorb these secondary electrons and produce acids. Then, the protecting group of the polymer may be substituted by the hydroxyl group, by the acids catalyze the deprotection reactions. As a result, the polymer may change its solubility in the given developer. When increasing acid generation yield, a lower EUV dose may be used without the deterioration of resolution. Thus, the sensitivity of the EUV photoresists may be related to the acid generation yield of CAR.

For the acid generation process of CAR in the EUV lithography process, there are two proposed mechanisms which are originated from PAG-cation reactions. First, the high energy (e.g., about 10˜82 eV) secondary electron may lose its energy to excite the electron from the highest occupied molecular orbital (HOMO) to the antibonding lowest unoccupied molecular orbital (LUMO) of the PAG molecule. Then, this excited PAG molecule may dissociate to produce acid. Otherwise, the low energy (e.g., lower than about 10 eV) secondary electron may be trapped by the antibonding LUMO of the PAG molecule, and it may be considered as causing a PAG decomposition and acid generation. Moreover, recent EUV lithography experiments on CAR with non-phenolic or anion-bound polymer demonstrated that PAG-cation reactions are the most dominant step for acid generation. However, detailed physical and chemical mechanisms of acid generation from PAG-cation molecules are still poorly understood.

According to example embodiments, a EUV sensitivity prediction model may be developed by systematically investigating the photochemical reaction and acid generation process of PAG-cation in both “electron trapping” and “internal excitation” mechanisms using atomic-scale molecules modeling. The method of predicting the EUV dose and method of designing the PAG according to example embodiments may be implemented by targeting triphenylsulfonium (Ph3S+/TPS) cation, which is a conventional PAG-cation molecule of photoresist components, and its derivative cations with symmetry and asymmetry functionalized substitution groups. For example, the entire photoreaction mechanism of the PAG-cation under the EUV exposure may be investigated, and the key parameter (e.g., the additional parameter affecting the EUV dose in addition to the LUMO energy level) for the acid generation and EUV exposure dose may be found. In addition, a two-parameter-based prediction model for PAG performance on EUV exposure dose may be developed based on experimental data. Finally, the design rules for synthesize new EUV PAG materials with superior properties may be suggested.

FIGS. 2 and 3 are block diagrams illustrating a prediction and design system according to example embodiments.

Referring to FIG. 2, a prediction and design system 1000 includes a processor 1100, a storage device 1200, and a prediction and design module 1300.

Herein, the term “module” may indicate, but is not limited to, a software and/or hardware component, such as a field programmable gate array (FPGA) or an application specific integrated circuit (ASIC), which performs certain tasks. A module may be configured to reside in a tangible addressable storage medium and be configured to execute on one or more processors. For example, a “module” may include components such as software components, object-oriented software components, class components and task components, and processes, functions, Routines, segments of program code, drivers, firmware, microcode, circuitry, data, databases, data structures, tables, arrays, and variables. A “module” may be divided into a plurality of “modules” that perform detailed functions.

The processor 1100 may be used when the prediction and design module 1300 performs computations or calculations. For example, the processor 1100 may include a microprocessor, an application processor (AP), a central processing unit (CPU), a digital signal processor (DSP), a graphic processing unit (GPU), a neural processing unit (NPU), or the like. Although FIG. 2 illustrates that the prediction and design system 1000 includes one processor 1100, example embodiments are not limited thereto. For example, the prediction and design system 1000 may include a plurality of processors. In addition, the processor 1100 may include cache memories to increase computation capacity.

The storage device 1200 may store data used for operations of the processor 1100 and the prediction and design module 1300. In some example embodiments, the storage device (or storage medium) 1200 may include any non-transitory computer-readable storage medium used to provide commands and/or data to a computer. For example, the non-transitory computer-readable storage medium may include a volatile memory such as a static random access memory (SRAM), a dynamic random access memory (DRAM), or the like, and a nonvolatile memory such as a flash memory, a magnetic random access memory (MRAM), a phase-change random access memory (PRAM), a resistive random access memory (RRAM), or the like. The non-transitory computer-readable storage medium may be inserted into the computer, may be integrated in the computer, or may be coupled to the computer through a communication medium such as a network and/or a wireless link.

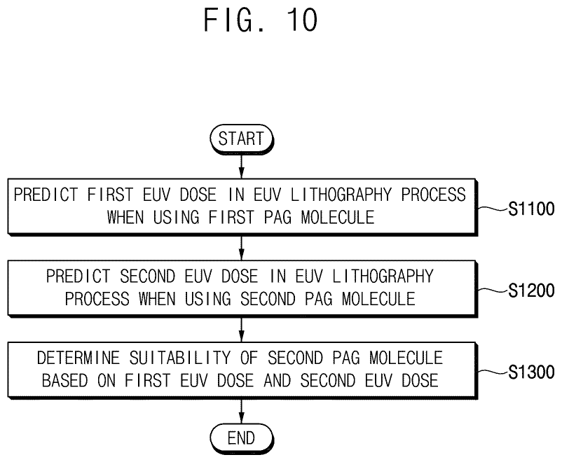

The prediction and design module 1300 may perform the method of predicting the EUV dose according to example embodiments described with reference to FIG. 1, and may perform a method of designing a PAG according to example embodiments which will be described with reference to FIG. 10. The prediction and design module 1300 may include an analysis module 1310, a simulation module 1320, and a determination module 1330.

The analysis module 1310 may perform analyzing operations to perform the method of predicting the EUV dose and/or the method of designing the PAG according to example embodiments. For example, the analysis module 1310 may analyze the entire photochemical reaction mechanism of the PAG, and may analyze various other data.

The simulation module 1320 may perform simulating operations to perform the method of predicting the EUV dose and/or the method of designing the PAG according to example embodiments. For example, the simulation module 1320 may perform simulations for structural optimization of molecular structures, and may perform various operations, processing, data generating and storing, etc., related thereto.

The determination module 1330 may perform determining (or judging) operations and result generating operations to perform the method of predicting the EUV dose and/or the method of designing the PAG according to example embodiments. For example, the determination module 1330 may generate a linear regression model based on results of the analyzing and simulating operations, and may determine a suitability of newly designed (or proposed) PAG structure.

For example, the analysis module 1310 may perform operation S100 in FIG. 1, the simulation module 1320 may perform operations S200 and S300 in FIG. 1, and the determination module 1330 may perform operation S400 in FIG. 1. For example, the analysis module 1310, the simulation module 1320 and the determination module 1330 may perform operations S1100 and S1200 in FIG. 10, and the determination module 1330 may perform operation S1300 in FIG. 10.

In some example embodiments, the analysis module 1310, the simulation module 1320 and the determination module 1330 may be implemented as instructions or program code that may be executed by the processor 1100. For example, the instructions or program code of the analysis module 1310, the simulation module 1320 and the determination module 1330 may be stored in computer readable medium. For example, the processor 1100 may load the instructions or program code to a working memory (e.g., a DRAM, etc.).

In other example embodiments, the processor 1100 may be manufactured to efficiently execute instructions or program code included in the analysis module 1310, the simulation module 1320 and the determination module 1330. For example, the processor 1100 may efficiently execute the instructions or program code from various artificial intelligence (AI) modules and/or machine learning modules. For example, the processor 1100 may receive information corresponding to the analysis module 1310, the simulation module 1320 and the determination module 1330 to operate the analysis module 1310, the simulation module 1320 and the determination module 1330.

In some example embodiments, the analysis module 1310, the simulation module 1320 and the determination module 1330 may be implemented as a single integrated module. In other example embodiments, the analysis module 1310, the simulation module 1320 and the determination module 1330 may be implemented as separate and different modules.

Referring to FIG. 3, a prediction and design system 2000 includes a processor 2100, an input/output (I/O) device 2200, a network interface 2300, a random access memory (RAM) 2400, a read only memory (ROM) 2500, and a storage device 2600. FIG. 3 illustrates an example where all of the analysis module 1310, the simulation module 1320 and the determination module 1330 in FIG. 2 are implemented in software.

The prediction and design system 2000 may be a computing system. For example, the computing system may be a fixed computing system such as a desktop computer, a workstation or a server, or may be a portable computing system such as a laptop computer.

The processor 2100 may be the same or substantially the same as the processor 1100 in FIG. 2. For example, the processor 2100 may include a core or a processor core for executing an arbitrary instruction set (for example, intel architecture-32 (IA-32), 64 bit extension IA-32, x86-64, PowerPC, Sparc, MIPS, ARM, IA-64, etc.). For example, the processor 2100 may access a memory (e.g., the RAM 2400 or the ROM 2500) through a bus, and may execute instructions stored in the RAM 2400 or the ROM 2500. As illustrated in FIG. 3, the RAM 2400 may store a program PR corresponding to the analysis module 1310, the simulation module 1320 and the determination module 1330 in FIG. 2 or at least some elements of the program PR, and the program PR may allow the processor 2100 to perform operations for predicting the EUV dose and/or designing the PAG according to example embodiments (e.g., operations S100, S200, S300 and S400 in FIG. 1 and/or operations S1100, S1200 and S1300 in FIG. 10).

In other words, the program PR may include a plurality of instructions and/or procedures executable by the processor 2100, and the plurality of instructions and/or procedures included in the program PR may allow the processor 2100 to perform the operations for predicting the EUV dose and/or designing the PAG according to example embodiments. Each of the procedures may denote a series of instructions for performing a certain task. A procedure may be referred to as a function, a routine, a subroutine, or a subprogram. Each of the procedures may process data provided from the outside and/or data generated by another procedure.

In some example embodiments, the RAM 2400 may include any volatile memory such as an SRAM, a DRAM, or the like.

The storage device 2600 may be substantially the same as the storage device 1200 in FIG. 2. For example, the storage device 2600 may store the program PR. The program PR or at least some elements of the program PR may be loaded from the storage device 2600 to the RAM 2400 before being executed by the processor 2100. The storage device 2600 may store a file written in a program language, and the program PR generated by a compiler or the like or at least some elements of the program PR may be loaded to the RAM 2400.

The storage device 2600 may store data, which is to be processed by the processor 2100, or data obtained through processing by the processor 2100. The processor 2100 may process the data stored in the storage device 2600 to generate new data, based on the program PR and may store the generated data in the storage device 2600.

The I/O device 2200 may include an input device, such as a keyboard, a pointing device, or the like, and may include an output device such as a display device, a printer, or the like. For example, a user may trigger, through the I/O devices 2200, execution of the program PR by the processor 2100, and may provide or check various inputs, outputs and/or data, etc.

The network interface 2300 may provide access to a network outside the prediction and design system 2000. For example, the network may include a plurality of computing systems and communication links, and the communication links may include wired links, optical links, wireless links, or arbitrary other type links. Various inputs may be provided to the prediction and design system 2000 through the network interface 2300, and various outputs may be provided to another computing system through the network interface 2300.

In some example embodiments, the computer program code, the analysis module 1310, the simulation module 1320 and/or the determination module 1330 may be stored in a transitory or non-transitory computer readable medium. In some example embodiments, values resulting from simulations performed by the processor or values obtained from arithmetic processing performed by the processor may be stored in a transitory or non-transitory computer readable medium. In some example embodiments, intermediate values generated during the simulations may be stored in a transitory or non-transitory computer readable medium. In some example embodiments, various data associated with or related to the simulations may be stored in a transitory or non-transitory computer readable medium. However, example embodiments are not limited thereto.

FIGS. 4 and 5 are diagrams for describing a method of predicting EUV dose according to example embodiments.

Referring to FIG. 4, the entire photochemical reaction mechanism until the PAG molecule releases the proton from the PAG-cation under the EUV exposure is illustrated. For example, the PAG-cation may be the TPS-cation, and FIG. 4 illustrates the photochemical reaction energy profile of TPS-cation under the EUV exposure. In FIG. 4, relative energy values with the TPS-cation are illustrated in eV unit.

As described above, the mechanism in which the acid is generated from the PAG may include “electron trapping” and “internal excitation”. As much as the band gap is narrow, the internal excitation may be easier (e.g., the acid may be more easily generated by the internal excitation) because electrons can easily excite to the LUMO level. Furthermore, as much as the LUMO level lowers, a secondary electron may be easily trapped in the LUMO level. Therefore, an efficiency of the electron trapping and the internal excitation process may strongly depend on the band gap and the LUMO level. To understand the overall deprotonation process of the PAG-cation, the detailed EUV photochemical reaction of the TPS-cation, which is a conventional PAG-cation, is investigated. For example, a TPS molecule may decompose to diphenylsulfide (or diphenylthioether) (DPS) and phenyl radical. Then, the excited or electron-trapped TPS may release acids by deprotonation during the rearrangement.

In some example embodiments, in the entire photochemical reaction mechanism in which the proton is released from the PAG-cation, a first molecular structure by the electron trapping; a second molecular structure and a second-first molecular structure by the internal excitation; a second-second molecular structure proceeding from the second molecular structure or the second-first molecular structure; a third molecular structure proceeding from the first molecular structure; a fourth molecular structure proceeding from the second molecular structure, the second-first molecular structure or the third molecular structure; and a fifth molecular structure proceeding from the fourth molecular structure or the second-second molecular structure and corresponding to a molecular structure after the proton is released from the PAG-cation; may be formed.

First, the mechanism related to the electron trapping may be described as follows. When the TPS-cation captures secondary electrons, which have relatively low energy (e.g., lower than about 10 eV), the TPS-cation may be spontaneously dissociated to a stable DPS molecule and a phenyl radical by the electron trapping, and thus the first molecular structure may be formed. For example, a structure indicated by label “1” in FIG. 4 may represent the first molecular structure, and may have an energy level of about −3.955 eV.

The phenyl radical decomposed from the first molecular structure may attack the ortho-position of the phenyl ring in the DPS molecule because that is the most sterically favored, and thus the third molecular structure may be formed. Not only based on kinetic probability but also thermal stability, 2(ortho)-(phenylthio) biphenyl may be made or created as the main product of the re-oriented phenyl substituted DPS isomer. For example, a structure indicated by label “3” in FIG. 4 may represent the third molecular structure, and may have an energy level of about −4.305 eV.

After the 2(ortho)-(phenylthio) biphenyl is generated or during the 2(ortho)-(phenylthio) biphenyl is generated, the 2(ortho)-(phenylthio) biphenyl may reduce other PAG-cations and may return to a cation. In other words, the third molecular structure may be oxidized to form the fourth molecular structure. For example, a structure indicated by label “4” in FIG. 4 may represent the fourth molecular structure, and may have an energy level of about −0.637 eV.

Thereafter, nearby PAG-anion or polymer may react with ortho-position hydrogen, and finally, the proton may be released from the PAG-cation, and thus the fifth molecular structure may be formed. For example, a structure indicated by label “5” in FIG. 4 may represent the fourth molecular structure, and may have an energy level of about −0.602 eV.

In addition, the mechanism related to the internal excitation may be described as follows. The coupling between secondary electrons which have relatively high energy may cause an electron excitation from HOMO to LUMO, and may induce the internal excitation in the TPS-cation. By such internal excitation, the TPS-cation may be dissociated to a DPS radical cation with phenyl radical, and thus the second molecular structure may be formed. Otherwise, by such internal excitation, the TPS-cation may be dissociated to a DPS molecule with phenyl cation, and thus the second-first molecular structure may be formed. For example, a structure indicated by label “2” in FIG. 4 may represent the second molecular structure, and may have an energy level of about 1.946 eV. For example, a structure indicated by label “2-1” in FIG. 4 may represent the second molecular structure, and may have an energy level of about 2.216 eV.

The proton may be released from the second molecular structure in which the TPS-cation is dissociated into the DPS radical cation with the phenyl radical, or the proton may be released from the second-first molecular structure in which the TPS-cation is dissociated into the DPS molecule with the phenyl cation, and thus the second-second molecular structure may be formed. For example, a structure indicated by label “2-2” in FIG. 4 may represent the second-second molecular structure.

Thereafter, it may proceed from the second molecular structure or the second-first molecular structure to the fourth molecular structure and the fifth molecular structure, or it may proceed from the second-second molecular structure to the fifth molecular structure, and finally, the proton may be released from the PAG-cation, and thus the fifth molecular structure may be formed.

Simulations may be performed based on the entire photochemical reaction mechanism illustrated in FIG. 4, and thus the additional parameter affecting the EUV dose in addition to the LUMO energy level may be obtained.

In some example embodiments, the additional parameter may include one of first deprotonation efficiency from the second molecular structure to the second-second molecular structure, second deprotonation efficiency from the fourth molecular structure to the fifth molecular structure, the amount of oxidation energy change from the third molecular structure to the fourth molecular structure, and the amount of overall energy change from the third molecular structure to the fifth molecular structure. In FIG. 4, the first deprotonation efficiency is indicated by “pKa(DPS)”, the second deprotonation efficiency is indicated by “pKa(rearranged)”, the amount of oxidation energy change is indicated by “ΔG_{oxidation}”, and the amount of overall energy change is indicated by “ΔGₜₒₜₐₗ”.

For example, atomic-scale molecules simulations may be performed based on the density functional theory (DFT) implemented in the Gaussian16 program package from Gaussian, Inc. Optimized structures of neutral, cation, and radical molecules/fragments in the gas phase may be computed with B3LYP functional and cc-pvdz atomic basis set. Gibbs free energy correction may be included by the B3LYP/6-31++g(d) level of single point frequency calculations of gas phase optimized structures. To include the solvation effect, the solvent condition may be approximated by the integral equation formalism variant polarizable continuum model (IEFPCM) with the propylene glycol methyl ether acetate (PGMEA) solvent. The Gibbs free energy and solvation effect calibrated parameters may be obtained by Equation 2.

$$\begin{matrix}Δ {G}_{solv} = H - T Δ S + ( Δ {E}_{PGMEA} - Δ {E}_{gas} ) \\ = Δ {G}_{gas} + ( Δ {E}_{PGMEA} - Δ {E}_{gas} )\end{matrix} \qquad [ Equation 2 ]$$

In Equation 2, ΔGₛₒₗᵥ denotes the Gibbs free energy including solvation effect, ΔG_{gas} denotes the Gibbs free energy at the gas phase, H denotes the enthalpy of the gas phase, TΔS denotes the entropy change of the system, ΔE_{PGMEA} denotes the internal energy of the PAG molecule by considering surrounding PGMEA solvent, and ΔE_{gas} denotes the internal energy of PAG molecule at the gas phase. All the Gibbs free energy term may mean solvation effect corrected value. To obtain deprotonation efficiency and oxidation barrier for intermediate molecular structures, following Equations may be defined. For example, the first deprotonation efficiency pKa(DPS), the second deprotonation efficiency pKa(rearranged), and the amount of oxidation energy change ΔG_{oxidation} mentioned as the additional parameters may be obtained by Equation 3, Equation 4, and Equation 5, respectively, and the amount of overall energy change ΔGₜₒₜₐₗ may be obtained by Equation 6 and Equation 7.

$$pKa ( DPS ) = ( Δ {G}_{{A}^{-}} + Δ {G}_{proton} ) - Δ {G}_{HA} \qquad [ Equation 3 ]$$

$$pKa ( rearranged ) = Δ {G}_{struct 5} + Δ {G}_{proton} ) - Δ {G}_{struct 4} \qquad [ Equation 4 ]$$

$$Δ {G}_{oxidation} = Δ {G}_{struct 4} - Δ {G}_{struct 3} \qquad [ Equation 5 ]$$

$$Δ {G}_{deprotonation} = ( Δ {G}_{struct 5} + Δ {G}_{proton} ) - Δ {G}_{struct 4} \qquad [ Equation 6 ]$$

$$\begin{matrix}Δ {G}_{total} = Δ {G}_{oxidation} + Δ {G}_{deprotonation} \\ = ( Δ {G}_{struct 5} + Δ {G}_{proton} ) - Δ {G}_{struct 3}\end{matrix} \qquad [ Equation 7 ]$$

For above Equations, theoretical Gibbs free energy value (e.g., about 262.4 kcal/mol) of the proton may be used, and the single point energy calculation may be performed to include PGMEA (e.g., ε=9.34) effect to obtain ΔGₚᵣₒₜₒₙ. In addition, each term may indicate the Gibbs free energy obtained by structural optimization for each molecular structure.

Another parameter that could represent the proton release ability may be introduced. For example, it may be denoted as pKa of thioether (e.g., DPS) and pKa of rearranged TPS. As the pKa parameter could be dramatically modulated by the functionalized group of diphenyl thiolether radical cation, it indicates that the pKa parameter of PAG-cation may be another dominant factor for predicting the EUV dose.

The above-described Equation 1 may be completed based on one of the above-described four additional parameters, e.g., one of the first deprotonation efficiency pKa(DPS), the second deprotonation efficiency pKa(rearranged), the amount of oxidation energy change ΔG_{oxidation}, and the amount of overall energy change ΔGₜₒₜₐₗ. In other words, in Equation 1, P_{after} may be one of pKa(DPS), pKa(rearranged), ΔG_{oxidation}, and ΔGₜₒₜₐₗ.

Referring to FIG. 5, example embodiments may include not only an example where the PAG-cation is the TPS-cation, but also an example where the PAG-cation can be extended to a modified structure of the TPS-cation as illustrated. For example, the PAG-cation may have a structure in which at least a portion of each phenyl ring or benzene ring included in the TPS-cation is modified.

For the PAG-cation to be extended to the modified structure of the TPS-cation, it is necessary to know the most dissociable phenyl ring among three phenyl rings included in the TPS-cation. In addition, when expanding the model to various asymmetric substituted-TPS compounds, which is different from three-fold symmetrized TPSs (e.g., the TPS-cation), it is necessary to know where the most dissociable phenyl ring will be attached.

First, singly occupied molecular orbital (SOMO) TPS or 1-substituted TPS or 2-substituted TPS may be compared to determine a dissociative phenyl ring. The hydroxyl group (—OH) may represent the electro-donating substituent groups (EDGs), and the trifluoromethane (—CF₃) may represent the electro-withdrawing substituent groups (EWGs). The antibonding orbital may change its position depending on the electro-donating/withdrawing property of the substituent groups. Nevertheless, for all the cases, the orbital node may locate on the bond between the Sulphur and phenyl ring with the most electron-rich phenyl ring. As a result, the relatively more electron-donating group-attached phenyl ring may dissociate from the Sulphur center. Because of the conjugation, the substituted-phenyl ring may dissociate as a radical fragment, and DPS may remain as a neutral fragment. Next, it may be significant that a substituted-phenyl radical will attack the more electron-rich site between two phenyl rings of DPS.

As described above, the regularity when the asymmetric TPS structure is dissociated may be obtained by the SOMO analysis. Based on this, it may be confirmed that example embodiments are applicable not only to an existing material (e.g., the TPS-cation) that is already used in the EUV lithography process, but also to a target material (e.g., the modified structure of the TPS-cation) that is to be newly designed for use in the EUV lithography process. In other words, based on the two-parameter linear regression model combining the LUMO energy level and one of the four additional parameters, the EUV dose may be efficiently predicted when various structures of TPS molecule-based material in which a substituent is bonded or not bonded to each carbon of each phenyl ring using the TPS molecule as a basic framework are used in the EUV lithography process.

FIGS. 6, 7, 8 and 9 are flowcharts illustrating examples of obtaining an additional parameter in FIG. 1.

Referring to FIGS. 1 and 6, when obtaining the additional parameter (operation S300), when the additional parameter includes the first deprotonation efficiency from the second molecular structure to the second-second molecular structure, the first deprotonation efficiency may be obtained by performing a simulation for structural optimization of the second molecular structure (operation S310). For example, the first deprotonation efficiency pKa(DPS) may be obtained based on Equation 3.

Referring to FIGS. 1 and 7, when obtaining the additional parameter (operation S300), when the additional parameter includes the second deprotonation efficiency from the fourth molecular structure to the fifth molecular structure, the second deprotonation efficiency may be obtained by performing a simulation for structural optimization of the fourth molecular structure (operation S320). For example, the second deprotonation efficiency pKa(rearranged) may be obtained based on Equation 4.

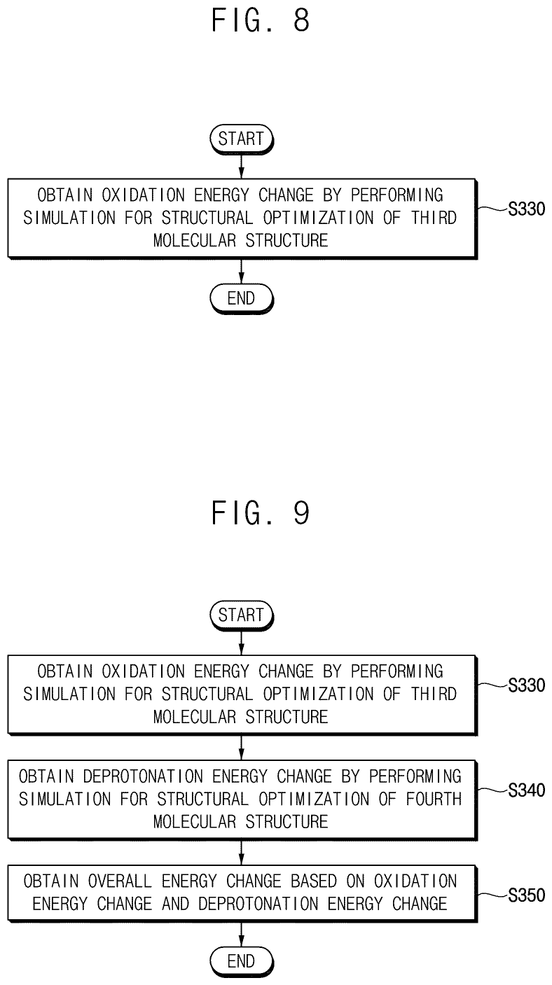

Referring to FIGS. 1 and 8, when obtaining the additional parameter (operation S300), when the additional parameter includes the amount of oxidation energy change from the third molecular structure to the fourth molecular structure, the amount of oxidation energy change may be obtained by performing a simulation for structural optimization of the third molecular structure (operation S330). For example, the amount of oxidation energy change ΔG_{oxidation} may be obtained based on Equation 5.

Referring to FIGS. 1 and 9, when obtaining the additional parameter (operation S300), when the additional parameter includes the amount of overall energy change from the third molecular structure to the fifth molecular structure, the amount of oxidation energy change may be obtained by performing a simulation for structural optimization of the third molecular structure (operation S330), the amount of deprotonation energy change may be obtained by performing a simulation for structural optimization of the fourth molecular structure (operation S340), and the amount of overall energy change may be obtained based on the amount of oxidation energy change and the amount of deprotonation energy change (operation S350). Operation S330 may be the same or substantially the same as that described with reference to FIG. 8. For example, the amount of deprotonation energy change ΔG_{deprotonation} may be obtained based on Equation 6, and the amount of overall energy change ΔGₜₒₜₐₗ may be obtained based on Equation 7.

A detailed process of performing two-parameter regression analysis based on the example of FIG. 9, e.g., based on the example where the additional parameter includes the amount of overall energy change ΔGₜₒₜₐₗ, may be described as follows. For example, the simulations may be performed using the Gaussian 16 program. However, example embodiments are not limited thereto, and various quantum chemical calculation tools capable of performing the DFT calculation, such as Q-Chem, ADF, NWChem, etc., may be used.

In operation S200, for PAG materials whose doses are measured under the same conditions, the energy, enthalpy, or Gibbs free energy may be calculated and the solvation effect may be corrected through structure optimization or vibrational energy calculation. For example, in this structure, the charge of the system may be +1, and the spin state may be singlet. For example, after the Gibbs free energy at the B3LYP/cc-pvdz level is calculated, the solvation effect by PGMEA may be reflected at the B3LYP/6-31++g(d) level. The molecular orbital energy level calculation may be performed on the obtained structure (e.g., the first molecular structure in FIG. 4). For example, calculation methodologies that include dispersion energy correction may be used as needed. For example, the LUMO energy level of the PAG may be obtained at the cam-B3LYP/aug-cc-pvdz level.

In operation S300, among the three phenyl rings of the PAG (e.g. the TPS), the phenyl ring with a substituent having the highest electro-donating effect (EDG) may be dropped, and this may result from the orbital structure illustrated in FIG. 5. The separated phenyl group may be bonded to the ortho-position of the phenyl ring on the side with a substituent with a high electro-donating effect among the remaining DPS. The structural optimization or Gibbs free energy calculation may be performed on the obtained structure (e.g., the third molecular structure in FIG. 4). For example, in this structure, since the secondary electron is captured, the charge of the system may be 0, and the spin state may be doublet. For example, the Gibbs free energy obtained in this structure may be ΔG_{struct3}.

Next, the structural optimization or Gibbs free energy calculation may be performed on the oxidized state (e.g., the fourth molecular structure in FIG. 4) of the obtained structure (e.g., the third molecular structure in FIG. 4) in which the separated phenyl group is bonded to the ortho-position. For example, in this structure, the charge of the system may be +1, and the spin state may be singlet. For example, the Gibbs free energy obtained in this structure may be ΔG_{struct4}. In some example embodiment, the operation of obtaining ΔG_{struct4} may be omitted.

Thereafter, the structural optimization or Gibbs free energy calculation may be performed on the final state (e.g., the fifth molecular structure in FIG. 4) in which the proton at the ortho-position attached to the phenyl ring is released from the oxidized state (e.g., the fourth molecular structure in FIG. 4). For example, in this structure, since the proton is released after the oxidation, the charge of the system may be 0, and the spin state may be singlet. For example, the Gibbs free energy obtained in this structure may be ΔG_{struct5}.

And finally, the amount of overall energy change ΔGₜₒₜₐₗ may be obtained based on Equation 7.

In operation S400, the two-parameter linear regression model such as Equation 1 may be obtained by performing the regression analysis based on the LUMO energy level obtained in operation S200 and the amount of overall energy change ΔGₜₒₜₐₗ obtained in operation S300.

FIG. 10 is a flowchart illustrating a method of designing a photoacid generator (PAG) according to example embodiments. The descriptions repeated with FIG. 1 will be omitted.

Referring to FIG. 10, a method of designing a photoacid generator (PAG) according to example embodiments may be performed in a design process for the PAG that is included in a specific material used in a manufacturing process of a semiconductor device (or semiconductor integrated circuit). For example, the material including the PAG may include a photoresist used in an EUV lithography process. For example, the method of designing the PAG according to example embodiments may be performed on a system and/or tool for performing an atomic-scale molecules simulation.

In the method of designing the PAG according to example embodiments, first EUV dose in an EUV lithography process when using a first PAG molecule is predicted (operation S1100), and second EUV dose in the EUV lithography process when using a second PAG molecule different from the first PAG molecule is predicted (operation S1200).

The first PAG molecule may be an existing material (or conventional material) that is already used in the EUV lithography process. The second PAG molecule may be a target material (or new material) that is to be newly designed for use in the EUV lithography process. In other words, the new PAG molecule may be designed and/or developed using the characteristics of the existing PAG molecule.

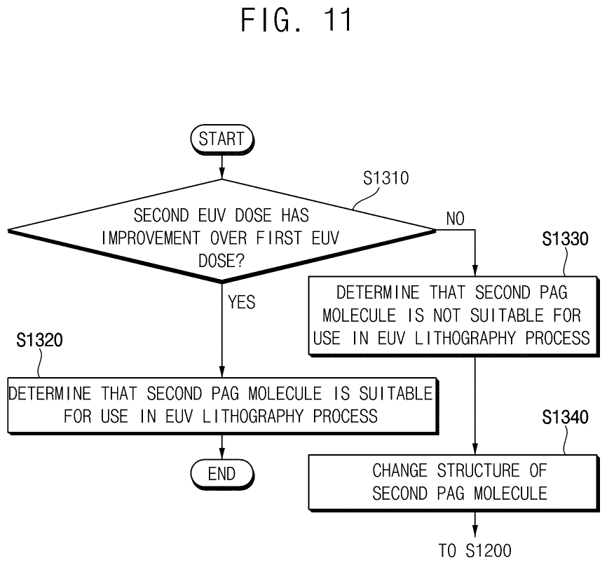

A suitability of the second PAG molecule is determined based on the first EUV dose and the second EUV dose (operation S1300). Operation S1300 will be described with reference to FIG. 11.

Each of operations S1100 and S1200 may be performed based on the method of predicting the EUV dose according to example embodiments described with reference to FIGS. 1 through 9.

For example, when predicting the first EUV dose, the first entire photochemical reaction mechanism until the first PAG molecule releases a first proton from a first PAG-cation under EUV exposure may be analyzed, a first LUMO energy level may be obtained by performing a simulation for structural optimization of the first PAG-cation, a first additional parameter different from the first LUMO energy level may be obtained by performing a simulation for structural optimization of at least one first intermediate molecular structure formed by the first entire photochemical reaction mechanism, and a first two-parameter linear regression model for predicting the first EUV dose may be obtained based on the first LUMO energy level and the first additional parameter.

When predicting the second EUV dose, the second entire photochemical reaction mechanism until the second PAG molecule releases a second proton from a second PAG-cation under EUV exposure may be analyzed, a second LUMO energy level may be obtained by performing a simulation for structural optimization of the second PAG-cation, a second additional parameter different from the second LUMO energy level may be obtained by performing a simulation for structural optimization of at least one second intermediate molecular structure formed by the second entire photochemical reaction mechanism, and a second two-parameter linear regression model for predicting the second EUV dose may be obtained based on the second LUMO energy level and the second additional parameter.

FIG. 11 is a flowchart illustrating an example of determining a suitability of a second PAG molecule in FIG. 10.

Referring to FIGS. 10 and 11, when determining the suitability of the second PAG molecule (operation S1300), it may be determined whether the second EUV dose has an improvement (or is improved) over the first EUV dose (operation S1310).

When the second EUV dose has the improvement over the first EUV dose (operation S1310: YES), e.g., when the second PAG molecule has a higher acid generation yield and the productivity of semiconductor devices is maintained or increased even if the second EUV dose becomes lower, it may be determined that the second PAG molecule is suitable for use in the EUV lithography process (operation S1320). In this case, the second PAG molecule may be manufactured, the second PAG molecule may be used in a manufacturing process (e.g., EUV lithography process), and the semiconductor devices may be manufactured using the newly developed and/or proposed second PAG molecule.

When the second EUV dose does not have the improvement over the first EUV dose (operation S1310: NO), e.g., when the acid generation yield of the second PAG molecule is not increased and the productivity of semiconductor devices is maintained only if the second EUV dose is higher than or equal to the first EUV dose, it may be determined that the second PAG molecule is not suitable for use in the EUV lithography process (operation S1330). In this case, the structure of the second PAG molecule may be changed (operation S1340), and operations S1200 and S1300 may be re-performed for the second PAG molecule whose structure has been changed. In other words, a new PAG molecule may be developed and/or proposed again.

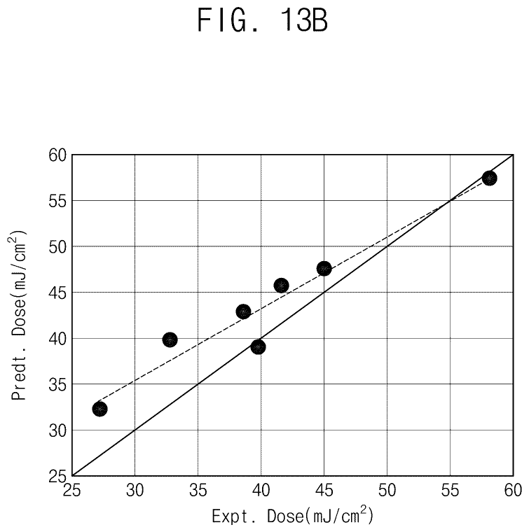

FIGS. 12A, 12B, 13A and 13B are diagrams for describing a method of designing a PAG according to example embodiments.

Referring to FIG. 12A, a TPS-cation is illustrated as an example of the first PAG molecule. The TPS-cation may have the entire photochemical reaction mechanism described with reference to FIG. 4.

Referring to FIG. 12B, a three-fold symmetric TPS-cation having a substituent is illustrated as an example of the first PAG molecule. For example, X may be one of —OH, —Ome, -tBu, -iPr, -Et, -Me, —H, —F, —I, —COMe, —CF₃, —CN, and —NO₂.

As a modified structure of the molecular structures illustrated in FIGS. 12A and 12B, a structure in which at least a portion of each phenyl ring is modified, e.g., one of various structures in which a substituent is bonded or not bonded to each carbon of each phenyl ring may be developed and/or proposed as the second PAG molecule in FIG. 10, and the performance of the second PAG molecule may be verified by the simulations.

Referring to FIG. 13A, results of the regression analysis for the above-described four additional parameters, e.g., the first deprotonation efficiency pKa(DPS), the second deprotonation efficiency pKa(rearranged), the amount of oxidation energy change ΔG_{oxidation}, and the amount of overall energy change ΔGₜₒₜₐₗ, are illustrated.

As compared with a result of predicting the EUV dose using only the LUMO energy level, it may be seen that the results of predicting the EUV dose are better in all cases using a first two-parameter linear regression model based on the LUMO energy level and the first deprotonation efficiency pKa(DPS), using a second two-parameter linear regression model based on the LUMO energy level and the second deprotonation efficiency pKa(rearranged), using a third two-parameter linear regression model based on the LUMO energy level and the amount of oxidation energy change ΔG_{oxidation}, and using a fourth two-parameter linear regression model based on the LUMO energy level and the amount of overall energy change ΔGₜₒₜₐₗ.

Referring to FIG. 13B, correlations between dose prediction values and dose experiment values are illustrated when using the fourth two-parameter linear regression model based on the LUMO energy level and the amount of overall energy change ΔGₜₒₜₐₗ.

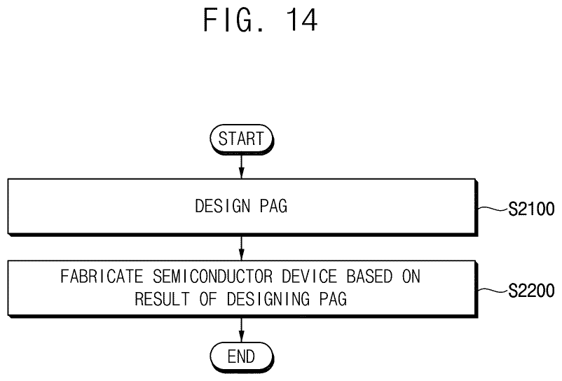

FIG. 14 is a flowchart illustrating a method of manufacturing a semiconductor device according to example embodiments.

Referring to FIG. 14, in a method of manufacturing a semiconductor device according to example embodiments, a PAG used in an EUV lithography process is designed (operation S2100), and the semiconductor device is fabricated based on a result of designing the PAG (operation S2200). Operation S2100 may be performed based on the method of designing the PAG according to example embodiments described with reference to FIGS. 10 and 11.

In operation S2200, the semiconductor device may be fabricated or manufactured by a mask, a wafer, a test, an assembly, packaging, and/or the like. For example, a photoresist including the PAG designed in operation S2100 may be manufactured. For example, the EUV lithography process may be performed using the photoresist, a photo mask, etc., various other processes such as an etching process may be performed, and desired patterns may be sequentially formed on a semiconductor substrate through these processes. Thereafter, the semiconductor device may be obtained in the form of a semiconductor chip through various additional processes.

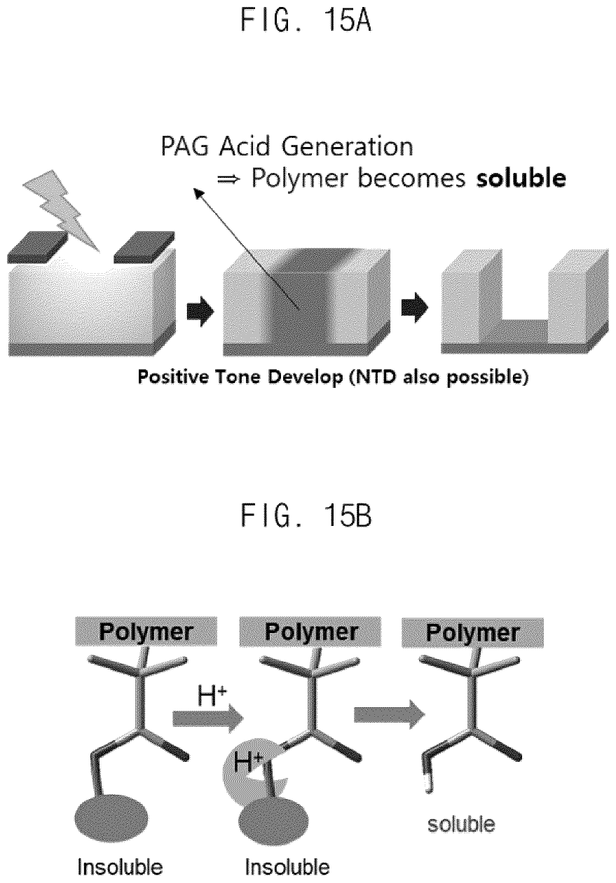

FIGS. 15A and 15B are diagrams for describing a method of manufacturing a semiconductor device according to example embodiments.

Referring to FIGS. 15A and 15B, an example of the EUV lithography process is conceptually illustrated.

An organic CAR photoresist used in the positive tone development (PTD) method may be a composite including (or composed of) a polymer, a PAG, a photo decomposable quencher (PDQ), etc. The part from which the protecting group of the polymer has been removed by the acid generated from the PAG or the polymer may be easily dissolved in the solvent, resulting in a difference in solubility from the part with the protecting group remaining. In other words, in the exposed area, the PAG may generate the acid and the protecting group of the polymer may be removed, resulting in a difference in solubility from the non-exposed area, thereby forming a pattern.

When the two-parameter linear regression model for the EUV dose is obtained using the LUMO energy level and the additional parameter according to example embodiments, the EUV dose may be efficiently predicted and the prediction consistency may be improved or enhanced based on the two-parameter linear regression model. In addition, a new PAG molecule that has superior performance (e.g., high acid generation yield) and is for forming patterns even at low EUV dose in the EUV lithography process, as compared with the existing PAG molecule, may be efficiently designed based on the method of predicting the EUV dose according to example embodiments.

Although example embodiments are described based on the two-parameter linear regression model, example embodiments are not limited thereto, and example embodiments may be extended and applied by using an N-parameter linear regression model, where N is a positive integer greater than or equal to three. For example, when N=3, the EUV dose may be predicted and the PAG molecule may be designed based on a three-parameter linear regression model obtained by Equation 8.

$$Dose = α \times L U M O + β \times P {1}_{after} + γ \times P {2}_{after} + δ \qquad [ Equation 8 ]$$

In Equation 8, “Dose” denotes the EUV dose, “LUMO” denotes the LUMO energy level, P1_{after} denotes a first additional parameter, P2_{after} denotes a second additional parameter, and α, β, γ and δ denote coefficients, respectively. For example, α may correspond to the contribution of the LUMO energy level, and β may correspond to the contribution of the first additional parameter, and γ may correspond to the contribution of the second additional parameter. For example, the first additional parameter and the second additional parameter may be the second deprotonation efficiency pKa(rearranged) and the amount of oxidation energy change ΔG_{oxidation}, respectively, but example embodiments are not limited thereto.

In addition, although example embodiments are described based on a method of predicting the EUV dose and a method of designing the PAG, example embodiments are not limited thereto, and example embodiments may be extended and applied to software development that predicts lithography properties and process characteristics such as dose, LER, LWR, CD variation, etc., based on various parameters. When designing a program that predicts lithography characteristics based on the physical properties of the material, it may be determined whether example embodiments are used by checking parameters used for dose prediction. For example, it may be determined whether example embodiments are used by checking whether mathematical equations according to example embodiments are implemented in program code.

As will be appreciated by those skilled in the art, inventive concepts may be embodied as a system, method, computer program product, and/or a computer program product embodied in one or more computer readable medium(s) having computer readable program code embodied thereon. The computer readable program code may be provided to a processor of a general purpose computer, special purpose computer, or other programmable data processing apparatus. The computer readable medium may be a computer readable signal medium or a computer readable storage medium. The computer readable storage medium may be any tangible medium that can contain or store a program for use by or in connection with an instruction execution system, apparatus, or device. For example, the computer readable medium may be a non-transitory computer readable medium.

Example embodiments may be applied to manufacture the semiconductor devices and/or the semiconductor integrated circuits. For example, example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a microprocessor, an application processor (AP), a central processing unit (CPU), an arithmetic logic unit (ALU), a digital signal processor (DSP), a microcomputer, a field programmable gate array (FPGA), a System-on-Chip (SoC), a programmable logic unit, a microprocessor, application-specific integrated circuit (ASIC), a graphic processing unit (GPU), a neural processing unit (NPU), etc. A processor may be one processor that performs the defined functions or a plurality of processors that collectively perform the defined functions such that the execution of the individual defined functions may be divided amongst such processors.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of predicting extreme ultraviolet (EUV) dose, the method being performed by executing program code by at least one processor, the program code being stored in a non-transitory computer readable medium, the method comprising:
analyzing an entire photochemical reaction mechanism until a photoacid generator (PAG) molecule releases a proton from a PAG-cation under EUV exposure;
obtaining a lowest unoccupied molecular orbital (LUMO) energy level by performing a simulation for structural optimization of the PAG-cation;
obtaining an additional parameter different from the LUMO energy level by performing a simulation for structural optimization of at least one intermediate molecular structure formed by the entire photochemical reaction mechanism; and
obtaining a two-parameter linear regression model for predicting the EUV dose based on the LUMO energy level and the additional parameter.

2. The method of claim 1, wherein, in the entire photochemical reaction mechanism,
a first molecular structure is formed by electron trapping;
a second molecular structure and a second-first molecular structure are formed by internal excitation;
a second-second molecular structure is formed proceeding from the second molecular structure or the second-first molecular structure;
a third molecular structure is formed proceeding from the first molecular structure;
a fourth molecular structure is formed proceeding from the second molecular structure, the second-first molecular structure or the third molecular structure; and
a fifth molecular structure is formed proceeding from the fourth molecular structure or the second-second molecular structure and corresponds to a molecular structure after the proton is released from the PAG-cation.

3. The method of claim 2, wherein the PAG-cation is a triphenylsulfonium (TPS)-cation.

4. The method of claim 3, wherein:
the first molecular structure corresponds to a structure in which the TPS-cation is dissociated to a diphenylsulfide (DPS) molecule and a phenyl radical,
the third molecular structure corresponds to a structure in which the phenyl radical decomposed from the first molecular structure attacks an ortho-position of phenyl ring in the DPS molecule,
the fourth molecular structure corresponds to an oxidized structure of the third molecular structure, and
the fifth molecular structure corresponds to a structure in which the TPS-cation releases the proton and is rearranged.

5. The method of claim 3, wherein:
the second molecular structure corresponds to a structure in which the TPS-cation is dissociated to a DPS radical cation with a phenyl radical,
the second-first molecular structure corresponds to a structure in which the TPS-cation is dissociated to a DPS molecule with a phenyl cation,
the second-second molecular structure corresponds to a structure in which the proton is released from the second molecular structure or the second-first molecular structure.

6. The method of claim 2, wherein the additional parameter includes an amount of overall energy change from the third molecular structure to the fifth molecular structure.

7. The method of claim 6, wherein the obtaining the additional parameter includes:
obtaining an amount of oxidation energy change by performing a simulation for structural optimization of the third molecular structure;
obtaining an amount of deprotonation energy change by performing a simulation for structural optimization of the fourth molecular structure; and
obtaining an amount of overall energy change based on the amount of oxidation energy change and the amount of deprotonation energy change.

8. The method of claim 2, wherein
the additional parameter includes an amount of oxidation energy change from the third molecular structure to the fourth molecular structure.

9. The method of claim 8, wherein the obtaining the additional parameter includes:
obtaining the amount of oxidation energy change by performing a simulation for structural optimization of the third molecular structure.

10. The method of claim 2, wherein the additional parameter includes a first deprotonation efficiency from the second molecular structure to the second-second molecular structure.

11. The method of claim 10, wherein obtaining the additional parameter includes:
obtaining the first deprotonation efficiency by performing a simulation for structural optimization of the second molecular structure.

12. The method of claim 2, wherein the additional parameter includes a second deprotonation efficiency from the fourth molecular structure to the fifth molecular structure.

13. The method of claim 12, wherein obtaining the additional parameter includes:
obtaining the second deprotonation efficiency by performing a simulation for structural optimization of the fourth molecular structure.

14. The method of claim 2, wherein the PAG-cation has a structure in which at least a portion of each phenyl ring included in the TPS-cation is modified.

15. A method of designing a photoacid generator (PAG), the method being performed by executing program code by at least one processor, the program code being stored in a non-transitory computer readable medium, the method comprising:
predicting a first extreme ultraviolet (EUV) dose in an EUV lithography process based on the EUV lithography process using a first PAG molecule;
predicting a second EUV dose in the EUV lithography process based on the EUV lithography process using a second PAG molecule, the second PAG molecule being different from the first PAG molecule; and
determining a suitability of the second PAG molecule based on the first EUV dose and the second EUV dose,
wherein the predicting the first EUV dose includes
analyzing a first entire photochemical reaction mechanism until the first PAG molecule releases a first proton from a first PAG-cation under EUV exposure,
obtaining a first lowest unoccupied molecular orbital (LUMO) energy level by performing a simulation for structural optimization of the first PAG-cation,
obtaining a first additional parameter different from the first LUMO energy level by performing a simulation for structural optimization of at least one first intermediate molecular structure formed by the first entire photochemical reaction mechanism, and
obtaining a first two-parameter linear regression model for predicting the first EUV dose based on the first LUMO energy level and the first additional parameter.

16. The method of claim 15, wherein predicting the second EUV dose includes:
analyzing a second entire photochemical reaction mechanism until the second PAG molecule releases a second proton from a second PAG-cation under EUV exposure;
obtaining a second LUMO energy level by performing a simulation for structural optimization of the second PAG-cation;
obtaining a second additional parameter different from the second LUMO energy level by performing a simulation for structural optimization of at least one second intermediate molecular structure formed by the second entire photochemical reaction mechanism; and
obtaining a second two-parameter linear regression model for predicting the second EUV dose based on the second LUMO energy level and the second additional parameter.

17. The method of claim 15, wherein:
the first PAG molecule is an existing material that is already used in the EUV lithography process, and
the second PAG molecule is a target material that is to be newly designed for use in the EUV lithography process.

18. The method of claim 17, wherein:
the first PAG-cation is a triphenylsulfonium (TPS)-cation, and
the second PAG-cation has a structure in which at least a portion of each phenyl ring included in the TPS-cation is modified.

19. The method of claim 15, wherein the determining the suitability of the second PAG molecule includes:
if the second EUV dose has an improvement over the first EUV dose, determining that the second PAG molecule is suitable for use in the EUV lithography process; or
if the second EUV dose does not have the improvement over the first EUV dose, determining that the second PAG molecule is not suitable for use in the EUV lithography process.

20. A method of predicting extreme ultraviolet (EUV) dose, the method being performed by executing program code by at least one processor, the program code being stored in a non-transitory computer readable medium, the method comprising:
analyzing an entire photochemical reaction mechanism until a photoacid generator (PAG) molecule releases a proton from a PAG-cation under EUV exposure,
in the entire photochemical reaction mechanism,
a first molecular structure is formed by electron trapping,
a second molecular structure and a second-first molecular structure are formed by internal excitation,
a second-second molecular structure is formed proceeding from the second molecular structure or the second-first molecular structure,
a third molecular structure is formed proceeding from the first molecular structure,
a fourth molecular structure is formed proceeding from the second molecular structure, the second-first molecular structure, or the third molecular structure, and
a fifth molecular structure is formed proceeding from the fourth molecular structure or the second-second molecular structure and corresponds to a molecular structure after the proton is released from the PAG-cation;
obtaining a lowest unoccupied molecular orbital (LUMO) energy level by performing a simulation for structural optimization from the PAG-cation to the first molecular structure;
obtaining an amount of overall energy change from the third molecular structure to the fifth molecular structure by performing a simulation for structural optimization from the third molecular structure to the fifth molecular structure; and
obtaining a two-parameter linear regression model for predicting the EUV dose based on the LUMO energy level and the amount of overall energy change,
wherein obtaining the additional parameter includes
obtaining an amount of oxidation energy change by performing a simulation for structural optimization of the third molecular structure,
obtaining an amount of deprotonation energy change by performing a simulation for structural optimization of the fourth molecular structure, and
calculating the amount of overall energy change based on the amount of oxidation energy change and the amount of deprotonation energy change, and
wherein the PAG-cation is a triphenylsulfonium (TPS)-cation or the PAG-cation has a structure in which at least a portion of each phenyl ring included in the TPS-cation is modified.
